(19) United States
(12) Patent Application Publication
(10) Pub. No.: US 2025/0189839 A1
(43) Pub. Date: Jun. 12, 2025

(54) ACTIVE MATRIX SUBSTRATE, IN-CELL TOUCH PANEL, AND DISPLAY DEVICE

(71) Applicant: Sharp Display Technology Corporation, Kameyama City (JP)

(72) Inventors: Hikaru YOSHINO, Kameyama City (JP); Shingo Kamitani, Kameyama City (JP); Junichi Morinaga, Kameyama City (JP)

(21) Appl. No.: 18/922,634

(22) Filed: Oct. 22, 2024

(30) Foreign Application Priority Data
Dec. 12, 2023 (JP) 2023-209709

(51) Int. Cl. G02F 1/1333; G02F 1/1343; G02F 1/1362; G06F 3/041; G06F 3/044; H01L 27/12

(52) U.S. Cl. CPC G02F 1/13338; G02F 1/136286; G06F 3/0412; G06F 3/04164; H10D 86/441; H10D 86/60; G02F 1/134372; G06F 3/044

(57) ABSTRACT

An active matrix substrate includes a plurality of source lines and a plurality of touch detection lines. Each of the plurality of touch detection lines includes a first portion and a second portion. The first portion extends along any one of the source lines in such a position as to overlap the source line. The second portion is placed in such a position as not to overlap the plurality of source lines. The second portions of adjacent touch detection lines are alternately arrayed side by side in a direction extending along the source line.

### BACKGROUND

### 1. Field

The present disclosure relates to an active matrix substrate, an in-cell touch panel, and a display device.

### 2. Description of the Related Art

An in-cell touch panel of Japanese Unexamined Patent Application Publication No. 2020-140075 has a dual gate structure. In other words, in this in-cell touch panel, gate lines extending in a row-wise direction are provided two by two for each boundary division between two pixels that are adjacent to each other in a column-wise direction. Further, data lines extending in the column-wise direction and touch detection lines extending in the column-wise direction are alternately arranged in the row-wise direction. Further, the data lines and the touch detection lines are each placed on a boundary division between two pixels that are adjacent to each other in the row-wise direction.

In an in-cell touch panel such as that described in Japanese Unexamined Patent Application Publication No. 2020-140075, increasing the number of touch detection electrodes for finer-resolution touch detection causes an increase in the number of touch detection lines. In a case where the number of touch detection lines is equal to the number of data lines, the data lines and the touch detection lines can be alternately arranged side by side; however, in a case where the number of touch detection lines is larger than the number of data lines, some of the touch detection lines are placed in such positions as to overlap some of the data lines. This causes a difference between the capacitance of a touch detection line placed over a data line and the capacitance of a touch detection line placed in such a position as not to overlap a data line. Due to this difference in capacitance, there are variations in the potential of a plurality of touch detection electrodes (i.e. the potential of a plurality of common electrodes). The variations in the potential of the plurality of touch detection electrodes undesirably lead to unevenness in display on the in-cell touch panel.

It is desirable to provide an active matrix substrate, an in-cell touch panel, and a display device that make it possible to increase the number of touch detection lines while avoiding unevenness in display.

### SUMMARY

According to an aspect of the disclosure, there is provided an active matrix substrate having a plurality of pixel regions arranged in a matrix in a first direction and a second direction intersecting the first direction. The active matrix substrate includes a plurality of gate lines, a plurality of source lines, and a plurality of touch detection lines. The plurality of gate lines extend in the first direction. The plurality of gate lines are arrayed in the second direction. The plurality of gate lines are formed in a gate line layer. The plurality of source lines extend in the second direction. The plurality of source lines are arrayed in the first direction. The plurality of source lines are formed in a source line layer. The plurality of touch detection lines are connected separately to each of a plurality of touch detection electrodes, arrayed in the first direction, and at least partly formed in a touch detection line layer. Each of the plurality of touch detection lines includes a first portion, a second portion, and a third portion. The first portion extends in the second direction in such a position as to overlap any one of the plurality of source lines. The first portion is formed in the touch detection line layer. The second portion extends in the second direction in such a position as not to overlap the plurality of source lines. The third portion connects the first portion to the second portion. The second portion of one of the plurality of touch detection lines and the second portion of a touch detection line that is adjacent to one of the plurality of touch detection lines in the first direction are alternately arrayed side by side in the second direction.

### BRIEF DESCRIPTION OF THE DRAWINGS

FIG. 1 is a cross-sectional view schematically showing a configuration of an in-cell touch panel according to a first embodiment;

FIG. 2 is a cross-sectional view schematically showing an active matrix substrate according to the first embodiment;

FIG. 3 is a plan view for explaining an arrangement of touch detection electrodes;

FIG. 4 is a circuit diagram for explaining a configuration of pixel regions formed in the active matrix substrate;

FIG. 5 is a diagram for explaining a configuration of touch detection lines;

FIG. 6 is a diagram for explaining where a black matrix is placed;

FIG. 7 is a diagram showing a configuration of an in-cell touch panel according to a second embodiment;

FIG. 8 is a diagram showing a configuration of an in-cell touch panel according to a third embodiment;

FIG. 9 is a diagram showing a configuration of an in-cell touch panel according to a fourth embodiment;

FIG. 10 is a diagram showing a configuration of an in-cell touch panel according to a fifth embodiment;

FIG. 11 is a diagram showing a configuration of an in-cell touch panel according to a sixth embodiment;

FIG. 12 is a diagram showing a configuration of an in-cell touch panel according to a seventh embodiment; and

FIG. 13 is a diagram showing a configuration of an in-cell touch panel according to an eighth embodiment.

### DESCRIPTION OF THE EMBODIMENTS

Embodiments of the present disclosure are described below with reference to the drawings. The present disclosure is not limited to the following embodiments and is subject to design change as appropriate to such an extent as to fulfill the configurations of the present disclosure. Further, in the following description, different drawings use identical signs in common for identical components or components having similar functions, and a repeated description thereof is omitted. Further, configurations described in the embodiments and modifications may be combined or changed as appropriate without departing from the scope of the present disclosure. For the sake of clarity, the drawings to be referred to below show a configuration in a simplified or illustrative manner and omit some constituent members. Further, the dimensional ratio between one constituent member and another shown in each drawing does not necessarily represent an actual dimensional ratio.

### First Embodiment

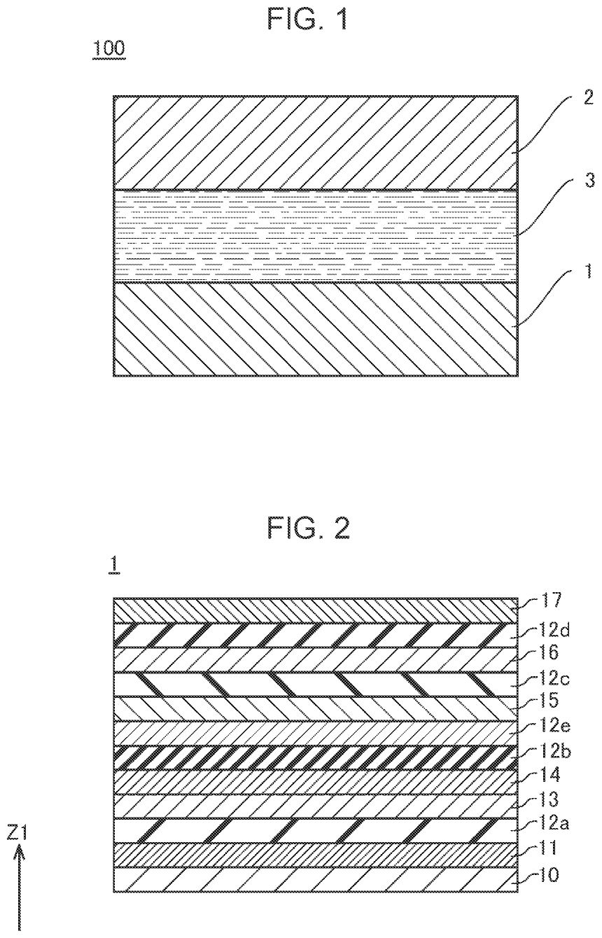

FIG. 1 is a cross-sectional view schematically showing a configuration of an in-cell touch panel 100 according to a first embodiment. FIG. 2 is a cross-sectional view schematically showing an active matrix substrate 1 according to the first embodiment.

The in-cell touch panel 100 is, for example, an in-plane switching liquid crystal display device. As shown in FIG. 1, the in-cell touch panel 100 is a display device including the active matrix substrate 1, a counter substrate 2, and a liquid crystal layer 3. The liquid crystal layer 3 is sandwiched between the active matrix substrate 1 and the counter substrate 2.

As shown in FIG. 2, the active matrix substrate 1 has a substrate 10, a gate line layer 11, a gate insulating layer 12a, a semiconductor layer 13, a source line layer 14, a first insulating layer 12b, a planarizing layer 12e, a touch detection line layer 15, a second insulating layer 12c, a common electrode layer 16, a third insulating layer 12d, and a pixel electrode layer 17 stacked on top of each other in this order. The gate line layer 11, the source line layer 14, and the touch detection line layer 15 each contain a metal material such as copper or aluminum. The gate insulating layer 12a, the first insulating layer 12b, the second insulating layer 12c, and the third insulating layer 12d are each composed of an insulator containing an inorganic material or an organic material. The planarizing layer 12e is composed of an organic material having photosensitivity. The common electrode layer 16 and the pixel electrode layer 17 are each composed of a transparent conductive film of, for example, ITO (indium tin oxide) or a mesh metal film.

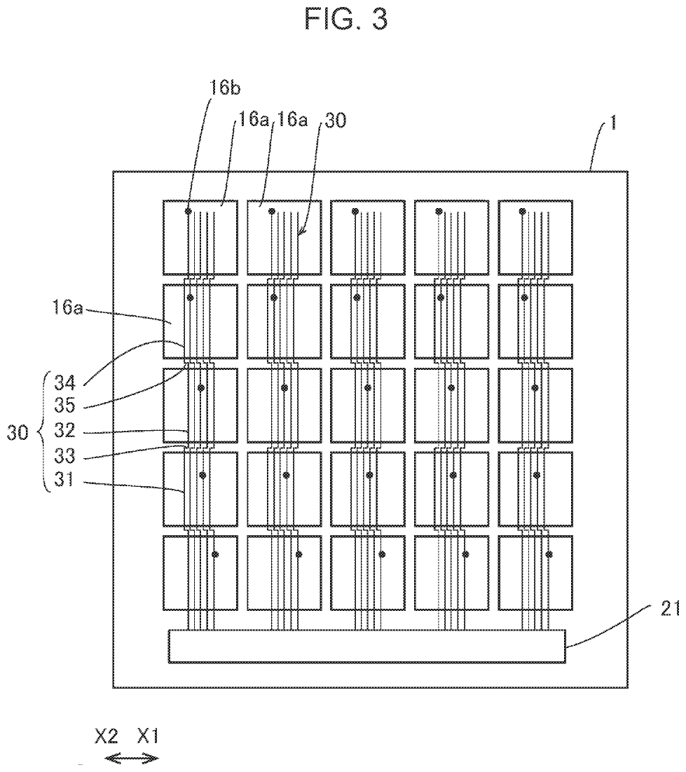

FIG. 3 is a plan view for explaining an arrangement of touch detection electrodes 16a. The active matrix substrate 1 has a plurality of the touch detection electrodes 16a formed in the common electrode layer 16 (see FIG. 2). The plurality of touch detection electrodes 16a are placed opposite a matrix arrangement of a plurality of pixel electrodes 17a in a direction normal to the active matrix substrate 1. The plurality of touch detection electrodes 16a are arranged in a matrix in an X1 direction and a Y1 direction. The active matrix substrate 1 is mounted with a driver including a touch detection circuit 21. The plurality of touch detection electrodes 16a are connected to the touch detection circuit 21 via touch detection lines 30. The touch detection circuit 21 executes a touch detection process of supplying each of the plurality of touch detection electrodes 16a with a driving signal, acquiring a detection signal from each of the plurality of touch detection electrodes 16a, and determining, in accordance with the detection signal, the presence or absence of a touch with an indicator (i.e. the location of a touch). The touch detection circuit 21 executes the touch detection process and a display process in a time-division manner. The display process by the touch detection circuit 21 is to apply a predetermined common potential to the plurality of touch detection electrodes 16a via the touch detection lines 30. The predetermined common potential serves as a reference for potentials that are supplied to the pixel electrodes 17a in activating liquid crystals in the liquid crystal layer 3.

Note here that the X1 direction is a rightward direction (row-wise direction) on the surface of paper on which FIG. 3 is drawn and that a direction opposite to the direction is an X2 direction. Further, the Y1 direction is a direction along a surface of the active matrix substrate 1 and a direction orthogonal to the X1 direction, and a direction opposite to the direction is a Y2 direction. Moreover, the direction normal to the active matrix substrate 1 is a Z1 direction, and a direction opposite to the direction is a Z2 direction.

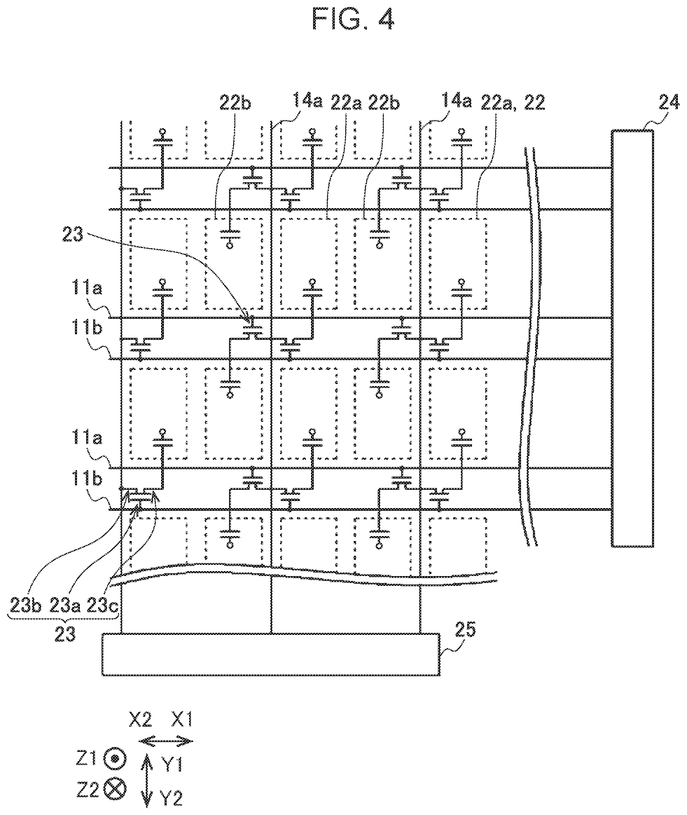

FIG. 4 is a circuit diagram for explaining a configuration of pixel regions 22 formed in the active matrix substrate 1. As shown in FIG. 4, the active matrix substrate 1 has formed therein a plurality of gate lines 11a extending in the X1 direction, a plurality of gate lines 11b extending in the X1 direction, and a plurality of source lines 14a extending in the Y1 direction. The plurality of gate lines 11a and the plurality of gate lines 11b are formed in the gate line layer 11. The plurality of source lines 14a are formed in the source line layer 14.

Each of the pixel regions 22 is a region in which a pixel electrode 17a is placed and a region that substantially contributes to a display. Each of the gate lines 11a is placed in a position that is further forward in the Y1 direction than a pixel region 22, and each of the gate lines 11b is placed in a position that is further forward in the Y2 direction than a pixel region 22. Further, a gate line 11a and a gate line 11b are placed between two pixel regions 22 that are adjacent to each other in the Y1 direction. That is, the first embodiment employs a dual gate driving method by which a row of pixel regions 22 is driven by two gate lines. Let it be assumed that a pixel region 22 connected to a gate line 11a is a pixel region 22a. Further, let it be assumed that a pixel region 22 connected to a gate line 11b is a pixel region 22b. The pixel regions 22a and 22b are alternately arranged in the X1 direction. Further, each of the source lines 14a is placed between pixel regions 22a and 22b that are adjacent to each other in the X1 direction. Each of the source lines 14a is placed in a position that is further forward in the X2 direction than a pixel region 22a and a position that is further forward in the X1 direction than a pixel region 22b. Moreover, none of the source lines 14a is placed in a position that is further forward in the X1 direction than a pixel region 22a and a position that is further forward in the X2 direction than a pixel region 22b. The source lines 14a are provided one by one for pixel regions 22a and 22b (i.e. two rows and columns of pixel regions). The pixel regions 22a and the pixel regions 22b are hereinafter referred to as “pixel regions 22” in a case where the pixel regions 22a and the pixel regions 22b are not distinguished from each other.

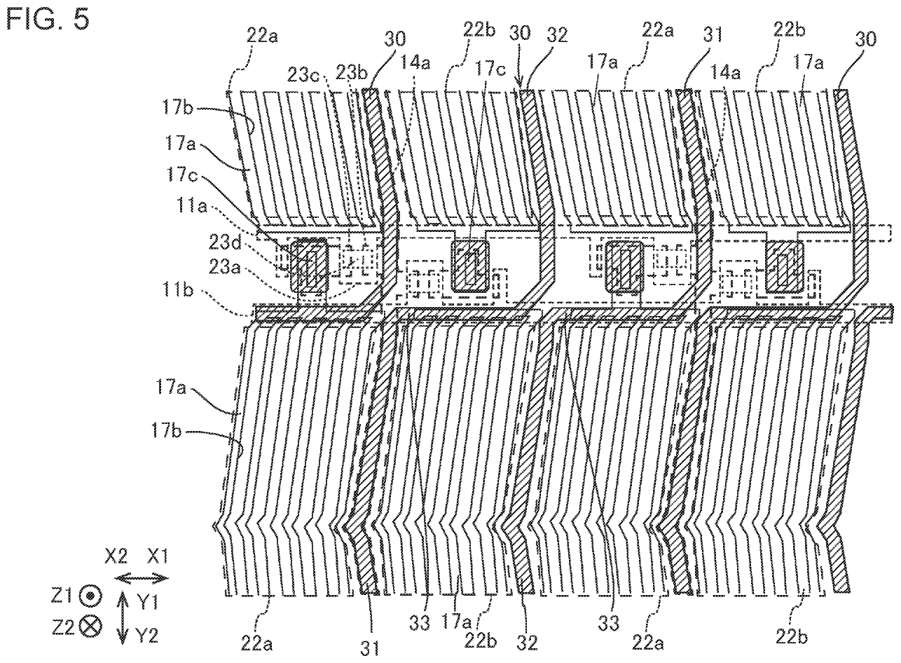

As shown in FIG. 4, transistor 23 are each placed between two pixel regions 22 that are adjacent to each other in the Y1 direction. Each of the transistors 23 includes a gate electrode 23a, a source electrode 23b, and a drain electrode 23c. The gate electrode 23a is formed in the gate line layer 11. Further, the gate electrode 23a is connected to a gate line 11a or a gate line 11b. The source electrode 23b is formed in the source line layer 14. Further, the source electrode 23b is connected to a source line 14a. The drain electrode 23c is formed in the source line layer 14. Further, the drain electrode 23c is connected to a pixel electrode 17a via a pixel contact hole 17c formed in the first insulating layer 12b, the planarizing layer 12e, the second insulating layer 12c, and the third insulating layer 12d. The pixel contact hole 17c is composed of a first pixel contact hole formed in the first insulating layer 12b and the planarizing layer 12e and a second pixel contact hole formed in the second insulating layer 12c and the third insulating layer 12d, and between the first pixel contact hole and the second pixel contact hole, an island-shaped electrode formed by the touch detection line layer 15 is placed. Further, an opening of a touch detection electrode 16a is formed in such a position as to overlap the pixel contact hole 17c in a plan view. The drain electrode 23c is connected to the island-shaped electrode via the first pixel contact hole, and the island-shaped electrode is connected to the pixel electrode 17a via the second pixel contact hole. Each of the transistors 23 is provided with a semiconductor component 23d (see FIG. 5) connected to the source electrode 23b and the drain electrode 23c.

The pixel electrodes 17a are formed in the pixel electrode layer 17 and each include a plurality of slits 17b extending along the source lines 14a. The touch detection electrodes 16a are common electrodes placed opposite the pixel electrodes 17a provided separately in each of the plurality of pixel regions 22. The active matrix substrate 1 has a gate driving circuit 24 and a source driving circuit 25 placed therein. The gate driving circuit 24 supplies gate signals in sequence to the plurality of gate lines 11a and 11b. The source driving circuit 25 supplies source signals to the plurality of source lines 14a. The gate driving circuit 24 is monolithically formed on top of the substrate 10 from the same film-forming material as the transistors 23 connected to the pixel electrodes 17. The source driving circuit 25 is included in a driver mounted on top of the substrate 10, or the source driving circuit 25 may be included in the same driver as the driver including the touch detection circuit 21 (see FIG. 2). Each of the transistors 23 receives, via the gate electrode 23a, a gate signal that brings the transistor 23 into an on state, supplies a corresponding one of the pixel electrodes 17a with a source signal from a corresponding one of the source lines 14a, and refreshes (rewrites) the potential of the pixel electrode 17a. Each of the pixel electrodes 17a generates an electric field between a corresponding one of the touch detection electrodes 16a and the pixel electrode 17a via the plurality of slits 17b formed in the pixel electrode 17a, thereby activating the liquid crystals in the liquid crystal layer 3 so that an image is displayed on the in-cell touch panel 100.

The touch detection lines 30 shown in FIG. 3 are connected to the touch detection electrodes 16a. The touch detection lines 30 are formed in the touch detection line layer 15 (see FIG. 2) via contact holes 16b formed in the second insulating layer 12c. Although there needs only be at least one contact hole 16b for each touch detection electrode 16a, there may be a plurality of contact holes 16b for each touch detection electrode 16a. In a case where there are a plurality of contact holes 16b for each touch detection electrode 16a, there is improvement in redundancy and a resistance distribution in each touch detection electrode 16a can be reduced.

FIG. 5 is a diagram for explaining a configuration of the touch detection lines 30. As shown in FIG. 5, each of the plurality of touch detection lines 30 includes a first portion 31, a second portion 32, and a third portion 33. The first portion 31 is a portion extending in the Y1 direction in such a position as to overlap one of the plurality of source lines 14a via the first insulating layer 12b and the planarizing layer 12e. The first portion 31 is placed between a pixel region 22a and a pixel region 22b. The phrase “extending in the Y1 direction” encompasses extending in a direction parallel with the Y1 direction and, as shown in FIG. 5, also encompasses extending at an angle to the Y1 direction. The second portion 32 is a portion extending in the Y1 direction in such a position as not to overlap the plurality of source lines 14a. The first portion 31 is placed in a position that is further forward in the X1 direction than the pixel region 22a and a position that is further forward in the X2 direction than the pixel region 22b. The second portion 32 is placed in a position that is further forward in the X1 direction than the pixel region 22b and a position that is further forward in the X2 direction than the pixel region 22a. In the first embodiment, in which the active matrix substrate 1 is configured to be driven by a dual gate driving method, there is a region where no source line is placed between a plurality of pixel regions 22 that are adjacent to each other in the X1 direction. This makes it possible to place the second portion 32 in that region. As a result of this, the second portion 32 does not overlap the pixel regions 22, so that blocking by the second portion 32 of light passing through the pixel regions 22 can be avoided. Further, as shown in FIG. 5, the number of touch detection lines 30 is twice as large as the number of source lines 14a.

The third portion 33 is a portion connecting the first portion 31 to the second portion 32. The third portion 33 extends in the X1 direction. Further, the third portion 33 is placed in such a position as to overlap a gate line 11b via the gate insulating layer 12a, the first insulating layer 12b, and the planarizing layer 12e. Further, the third portion 33 is placed between two pixel regions 22 that are adjacent to each other in the Y1 direction. Further, as shown in FIG. 3, the third portion 33 is placed between two touch detection electrodes 16a that are adjacent to each other in the Y1 direction.

In the first embodiment, as shown in FIG. 5, each of the plurality of touch detection lines 30 is provided with a first portion 31 and a second portion 32. Furthermore, the second portion 32 of one of the plurality of touch detection lines 30 and the second portion 32 of a touch detection line 30 that is adjacent to one of the plurality of touch detection lines 30 in the X1 direction are alternately arrayed side by side in the Y1 direction. According to this, even in a case where the number of touch detection lines 30 is increased, a situation where only a particular one of the plurality of touch detection lines 30 includes a portion overlapping a source line 14a is avoided, and each of the plurality of touch detection lines 30 includes a portion overlapping a source line 14a and a portion not overlapping a source line 14a. Therefore, there is no increase in capacitance that is formed between only a particular touch detection line and a source line 14a, and the difference between the capacitance of one of the plurality of touch detection lines 30 and the capacitance of another touch detection line 30 that is adjacent to one of the plurality of touch detection lines 30 in the X1 direction can be reduced, so that variations in the capacitance of the plurality of touch detection lines 30 can be reduced. As a result of this, variations in the potential of the plurality of touch detection electrodes 16a can be reduced, so that unevenness in display on the in-cell touch panel 100 can be avoided.

As shown in FIG. 3, each of the plurality of touch detection lines 30 further includes a fourth portion 34 formed as an extension in the Y1 direction of the first portion 31 and a fifth portion 35 connecting the fourth portion 34 to the second portion 32. The fifth portion 35 extends in the X2 direction from the second portion 32 toward the fourth portion 34. The fifth portion 35 is placed between two touch detection electrodes 16a that are adjacent to each other in the Y1 direction and, as is the case with the third portion 33, overlaps a gate line 11b via the gate insulating layer 12a, the first insulating layer 12b, and the planarizing layer 12e. As shown in FIG. 3, the touch detection lines 30 are disposed to extend in the Y1 direction while meandering in the X1 direction and the X2 direction.

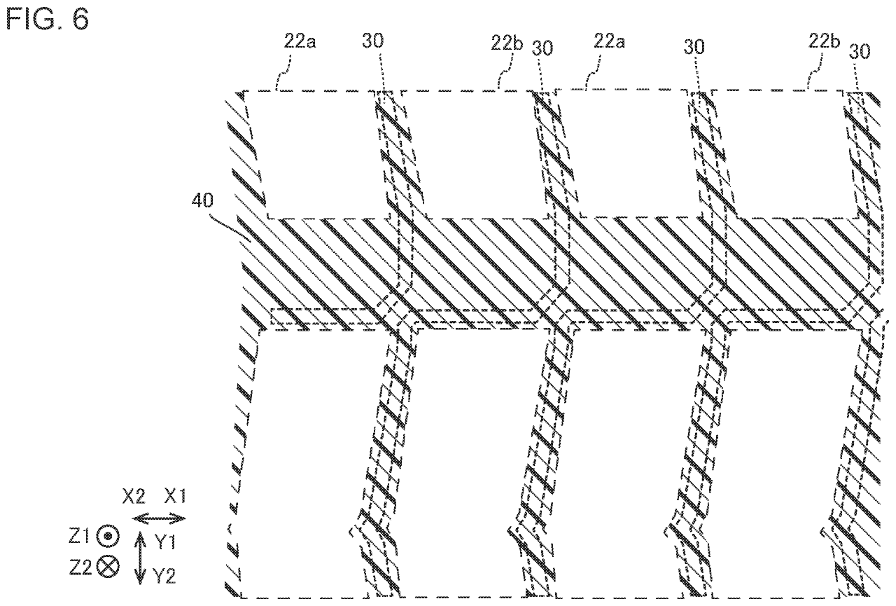

FIG. 6 is a diagram for explaining where a black matrix 40 is placed. As shown in FIG. 6, the counter substrate 2 is provided with the black matrix 40. The black matrix 40 is a light-blocking member. The black matrix 40 is placed between the plurality of pixel regions 22 and overlaps the semiconductor components 23d of the transistors 23 and the pixel contact holes 17c. Further, any of the first to fifth portions 31 to 35 of the touch detection lines 30 are placed in such positions as to overlap the black matrix 40. This makes it possible to avoid the touch detection lines 30 affecting a display.

### Second Embodiment

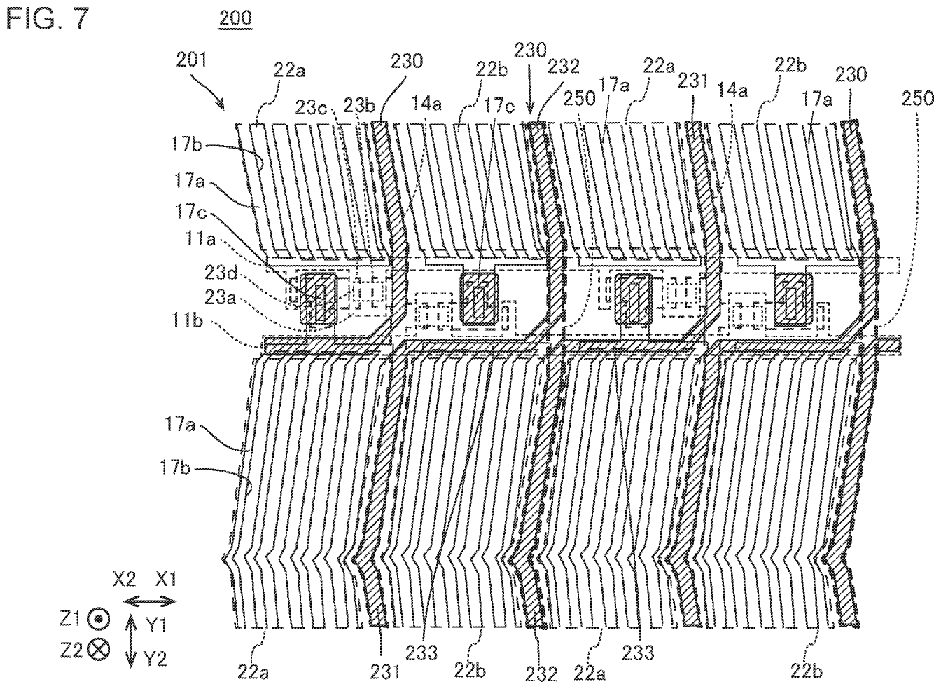

Next, a configuration of an in-cell touch panel 200 according to a second embodiment is described with reference to FIG. 7. In the second embodiment, dummy lines 250 are placed in such positions as to overlap second portions 232 of touch detection lines 230. Components that are similar to those of the first embodiment are given the same reference signs as those of the first embodiment, and a description of such components is omitted. The “dummy lines 250” are examples of “conductor lines” of the present disclosure.

FIG. 7 is a diagram showing the configuration of the in-cell touch panel 200 according to the second embodiment. The in-cell touch panel 200 includes an active matrix substrate 201. The active matrix substrate 201 includes dummy lines 250 extending in the Y1 direction. The dummy lines 250 are conductor lines that are different from the plurality of source lines 14a and conductor lines formed in the source line layer 14 (see FIG. 2). Each of the dummy lines 250 is placed in a position that is further forward in the X2 direction than a pixel region 22a and a position that is further forward in the X1 direction than a pixel region 22b. The dummy lines 250 are conductor lines that are not connected to the source driving circuit 25 (see FIG. 4) or that are not supplied with source signals from the source driving circuit 25. That is, the dummy lines 250 are conductor lines that do not function as source lines. The dummy lines 250 are supplied, for example, with a common potential.

As shown in FIG. 7, each of the touch detection lines 230 includes a first portion 231 placed in such a position as to overlap a source line 14a, a second portion 232 placed in such a position as not to overlap a source line 14a, and a third portion 233 connecting the first portion 231 to the second portion 232. Each of the dummy lines 250 is placed in such a position as to overlap the second portion 232 of a touch detection line 230. For this reason, the first portion 231 of each of the touch detection lines 230 overlaps a source line 14a, and the second portion 232 of each of the touch detection lines 230 overlaps a dummy line 250. In the first embodiment, there is a case in which the difference between capacitance that is formed by a first portion 31 overlapping a source line 14a and capacitance that is formed by a second portion 32 not overlapping a source line 14a is great, and depending on the number and size of touch detection electrodes 16a or the positions of the contact holes 16b, there is a case in which the difference between the capacitance of a certain touch detection line 30 and the capacitance of a touch detection line 30 that is adjacent to that touch detection line 30. In the second embodiment, providing a dummy line 250 overlapping a second portion 232 makes it possible to adjust capacitance that is formed by the second portion 232, thereby reducing the difference between the capacitance of the first portion 231 and the capacitance of the second portion 232. Other components and effects of the second embodiment are similar to the components and effects of the first embodiment.

### Third Embodiment

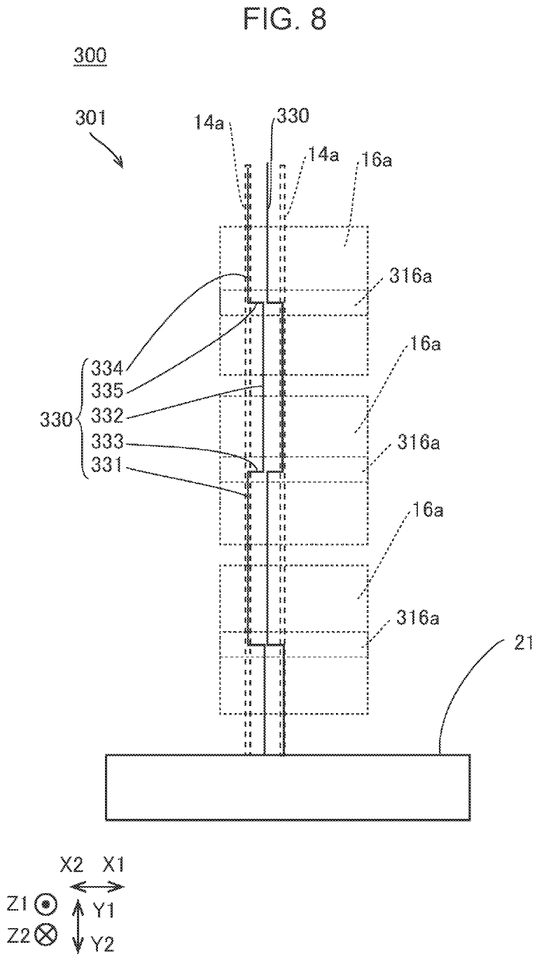

Next, a configuration of an in-cell touch panel 300 according to a third embodiment is described with reference to FIG. 8. In the third embodiment, a third portion 333 of a touch detection line 330 is placed in such a position as to overlap a central portion 316a of a touch detection electrode 16a. Components that are similar to those of the first embodiment are given the same reference signs as those of the first embodiment, and a description of such components is omitted.

FIG. 8 is a diagram showing the configuration of the in-cell touch panel 300 according to the third embodiment. The in-cell touch panel 300 includes an active matrix substrate 301. The active matrix substrate 301 includes a touch detection line 330. The touch detection line 330 includes a first portion 331, a second portion 332, a third portion 333, a fourth portion 334, and a fifth portion 335. The first portion 331 and the fourth portion 334 are placed in such positions as to overlap a source line 14a. The second portion 332 is placed in such a position as not to overlap a source line 14a. The third portion 333 and the fifth portion 335 are placed in such positions as to overlap a central portion 316a of a touch detection electrode 16a. The central portion 316a is a central portion of the touch detection electrode 16a in the Y1 direction. The third portion 333 and the fifth portion 335 are placed, for example, in center positions in the Y1 direction of the touch detection electrode 16a. The central portion 316a is, for example, a region that is further forward in the Y1 direction than an end portion in the Y2 direction of the touch detection electrode 16a and a region that is further forward in the Y2 direction than an end portion in the Y1 direction of the touch detection electrode 16a. Further, as with the third portion 33 of the first embodiment, the third portion 333 and the fifth portion 335 are placed between two pixel regions 22 that are adjacent to each other in the Y1 direction. The third embodiment makes it possible to substantially equalize the capacitance of a plurality of the touch detection lines 330 in regions overlapping the touch detection electrodes 16a. Other components and effects of the third embodiment are similar to the components and effects of the first embodiment.

### Fourth Embodiment

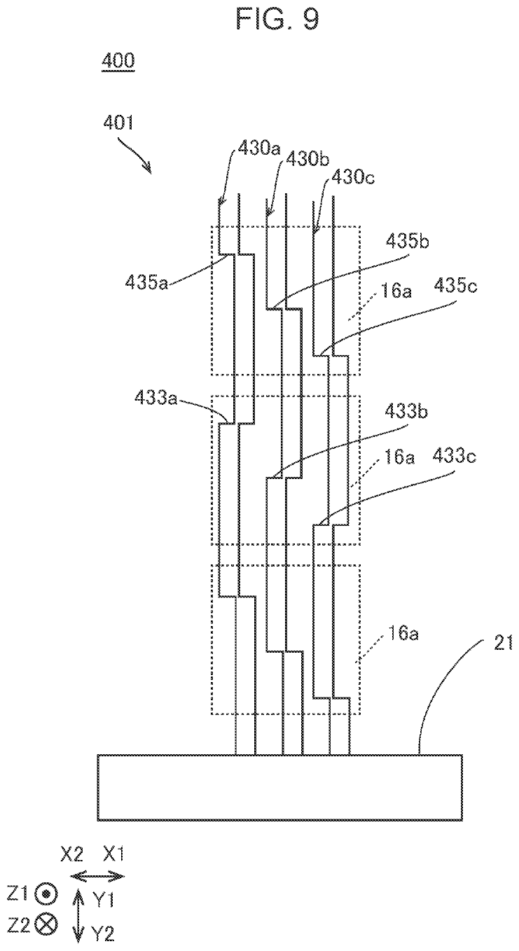

Next, a configuration of an in-cell touch panel 400 according to a fourth embodiment is described with reference to FIG. 9. In the fourth embodiment, third portions of touch detection lines 430a to 430c are placed in positions that are different from one another in the Y1 direction. Components that are similar to those of the first embodiment are given the same reference signs as those of the first embodiment, and a description of such components is omitted.

FIG. 9 is a diagram showing the configuration of the in-cell touch panel 400 according to the fourth embodiment. The in-cell touch panel 400 includes an active matrix substrate 401. The active matrix substrate 401 includes a touch detection line 430a, a touch detection line 430b, and a touch detection line 430c. The touch detection line 430a includes third portions 433a and 435a. The touch detection line 430b includes third portions 433b and 435b. The touch detection line 430c includes third portions 433c and 435c.

As shown in FIG. 9, the third portion 433a is placed in a position that is further forward in the Y1 direction than the third portion 433b and the third portion 433c. The fifth portion 435a is placed in a position that is further forward in the Y1 direction than the fifth portion 435b and the fifth portion 435c. Further, the third portion 433b is placed in a position that is further forward in the Y1 direction than the third portion 433c. The fifth portion 435b is placed in a position that is further forward in the Y1 direction than the fifth portion 435c. That is, the third portions of the touch detection lines 430a to 430c are dispersedly placed in positions that are different from one another in the Y1 direction. In the third embodiment, as in the case of the third portion 33 or the fifth portion 35 of the first embodiment, in a case where the third portion 333 or the fifth portion 335 overlaps a gate line, a particular gate line, i.e. a gate line overlapping the third portion 333 or the fifth portion 335, is larger in capacitance than other gate lines, so that there may be a difference in the way gate signals become blunt. In this case, a display on particular pixel regions aligned in the row-wise direction is not appropriate and may be visually recognized by a user as horizontal streaks on the in-cell touch panel 400. As shown in FIG. 9, dispersing the third portions or fifth portions of the touch detection lines 430a to 430c in positions that are different from one another in the Y1 direction makes it possible to avoid a situation where a difference in capacitance between gate lines attributed to the third portions affects a display. Other components and effects of the fourth embodiment are similar to the components and effects of the first embodiment.

### Fifth Embodiment

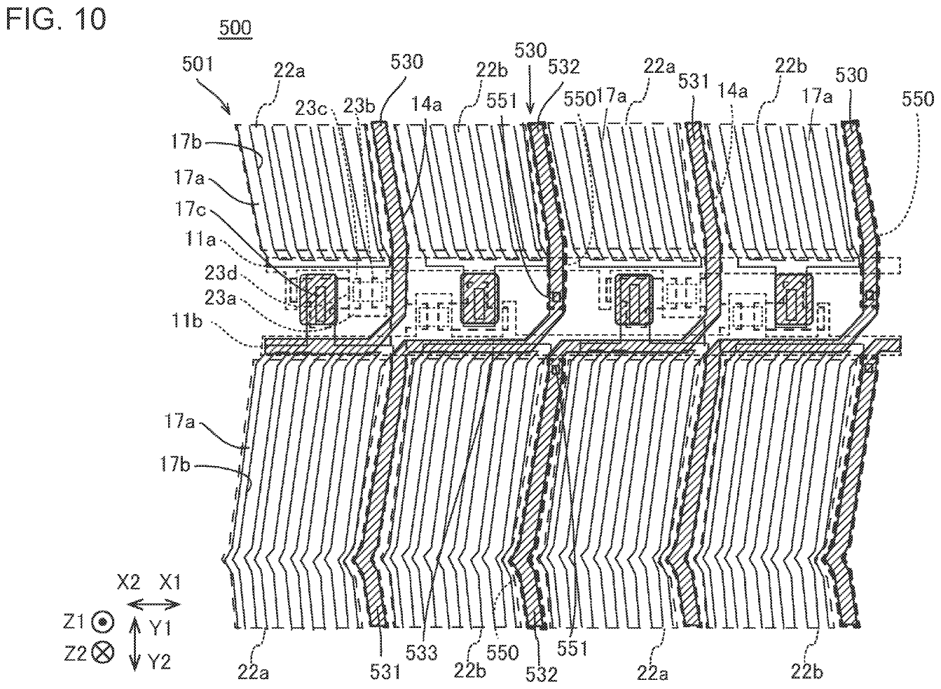

Next, a configuration of an in-cell touch panel 500 according to a fifth embodiment is described with reference to FIG. 10. In the fifth embodiment, conductor lines 550 connected to second portions 532 of touch detection lines 530 are placed in such positions as to overlap the second portions 532. Components that are similar to those of the first embodiment are given the same reference signs as those of the first embodiment, and a description of such components is omitted.

FIG. 10 is a diagram showing the configuration of the in-cell touch panel 500 according to the fifth embodiment. The in-cell touch panel 500 includes an active matrix substrate 501. The active matrix substrate 501 includes conductor lines 550 extending in the Y1 direction. The conductor lines 550 are conductor lines that are different from the plurality of source lines 14a and conductor lines formed in the source line layer 14 (see FIG. 2). Each of the conductor lines 550 is placed in a position that is further forward in the X2 direction than a pixel region 22a and a position that is further forward in the X1 direction than a pixel region 22b.

As shown in FIG. 10, each of the touch detection lines 530 includes a first portion 531 placed in such a position as to overlap a source line 14a, a second portion 532 placed in such a position as not to overlap a source line 14a, and a third portion 533 connecting the first portion 531 to the second portion 532. Each of the conductor lines 550 is placed in such a position as to overlap the second portion 532 of a touch detection line 530. Moreover, the conductor lines 550 are connected to the second portions 532 via contact holes 551 formed in the first insulating layer 12b and the planarizing layer 12e. At least two of the contact holes 551 are provided in correspondence with each of the second portions 532. This makes it possible to reduce the electric resistance of the touch detection lines 530. Further, since the conductor lines 550 can be utilized as redundant lines of the touch detection lines 530, the redundancy of the in-cell touch panel 500 can be improved. Other components and effects of the fifth embodiment are similar to the components and effects of the first embodiment.

### Sixth Embodiment

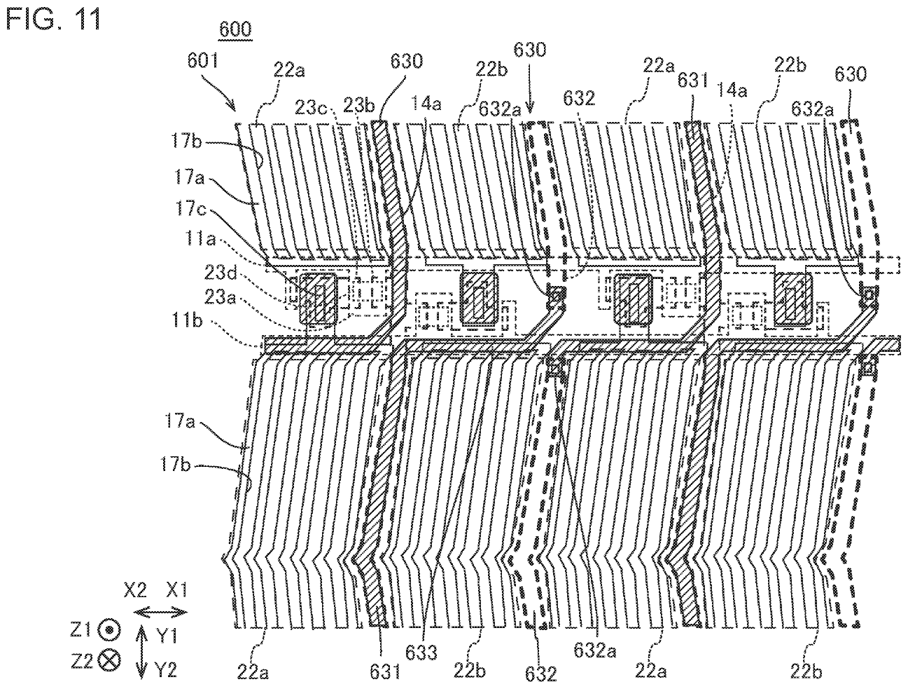

Next, a configuration of an in-cell touch panel 600 according to a sixth embodiment is described with reference to FIG. 11. In the sixth embodiment, second portions 632 of touch detection lines 630 are formed in the source line layer 14. Components that are similar to those of the first embodiment are given the same reference signs as those of the first embodiment, and a description of such components is omitted.

FIG. 11 is a diagram showing the configuration of the in-cell touch panel 600 according to the sixth embodiment. The in-cell touch panel 600 includes an active matrix substrate 601. The active matrix substrate 601 includes the touch detection lines 630. Each of the touch detection lines 630 includes a first portion 631 placed in such a position as to overlap a source line 14a, a second portion 632 placed in such a position as not to overlap a source line 14a, and a third portion 633 connecting the first portion 631 to the second portion 632. The second portion 632 is formed in the source line layer 14 (see FIG. 2). The second portion 632 is connected to the third portion 633 via a contact hole 632a formed in the first insulating layer 12b and the planarizing layer 12e. In the first embodiment, the second insulating layer 12c is sandwiched between a second portion 32 formed in the touch detection line layer 15 and a touch detection electrode 16a; meanwhile, in the sixth embodiment, the first insulating layer 12b, the planarizing layer 12e, and the second insulating layer 12c are sandwiched between a second portion 632 formed in the source line layer 14 and a touch detection electrode 16a. This makes it possible to reduce capacitance that is formed between the second portion 632 and the touch detection electrode 16a. Other components and effects of the sixth embodiment are similar to the components and effects of the first embodiment.

### Seventh Embodiment

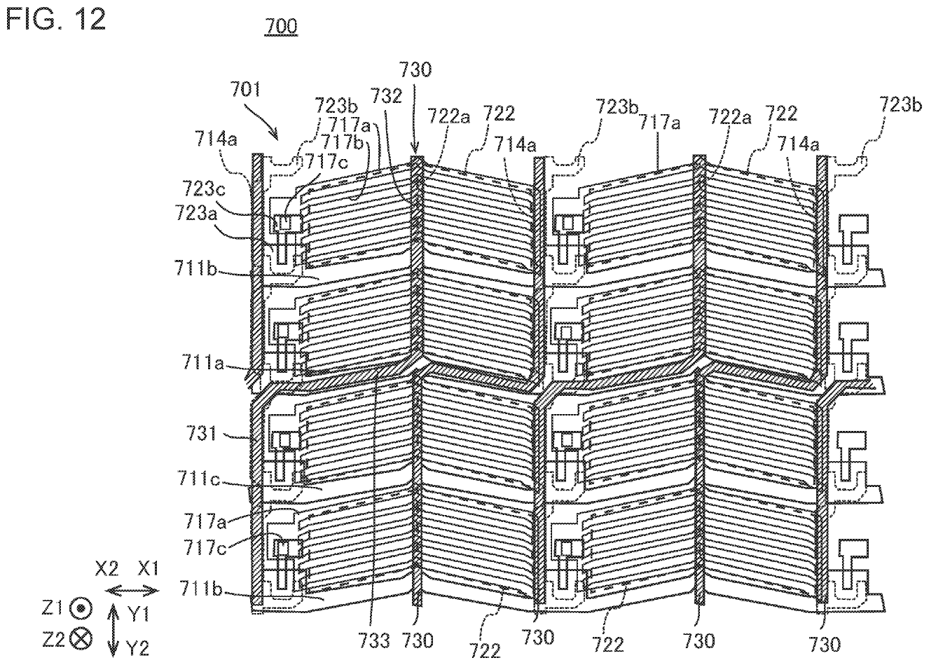

Next, a configuration of an in-cell touch panel 700 according to a seventh embodiment is described with reference to FIG. 12. In the seventh embodiment, an active matrix substrate 701 is configured to be driven by a triple gate driving method. Components that are similar to those of the first embodiment are given the same reference signs as those of the first embodiment, and a description of such components is omitted.

FIG. 12 is a diagram showing the configuration of the in-cell touch panel 700 according to the seventh embodiment. The in-cell touch panel 700 includes an active matrix substrate 701. The active matrix substrate 701 includes pixel regions 722 (pixel electrodes), source lines 714a extending in the Y1 direction, gate lines 711a to 711c extending in the X1 direction and bent into V shapes between adjacent ones of the source lines 714a, and touch detection lines 730. In the seventh embodiment, the number of pixel regions 722 per row is ⅓ of that of the first embodiment, and the number of pixel regions 722 per column is three times as large as that of the first embodiment. Further, the number of source lines 714a is ⅓ of that of the after-mentioned eighth embodiment (single gate), and the number of gate lines (gate lines 711a to 711c) is three times as large as that of the eighth embodiment (single gate). That is, the active matrix substrate 701 is configured to be driven by a triple gate driving method.

Further, as shown in FIG. 12, each of the pixel regions 722 has a kink portion 722a that is a central portion in the X1 direction of the pixel region 722, and the kink portion 722a is placed in a position that is furthest forward in the Y1 direction. Moreover, an end portion in the X1 direction and an end portion in the X2 direction of each of the pixel regions 722 are placed in positions that are further forward in the Y2 direction than the kink portion 722a. That is, each of the pixel regions 722 (pixel electrodes) and pixel electrodes 717a has formed therein a plurality of slits 717b bent along the gate lines 711a to 711c at the kink portion 722a in a plan view. Further, a gate electrode 723a, a source electrode 723b, and a drain electrode 723c are placed in positions that are further forward in the X2 direction than each of the pixel regions 722. Further, the pixel electrode 717a and the drain electrode 723c are connected to each other via a pixel contact hole 717c.

Each of the touch detection lines 730 includes a first portion 731 placed in such a position as to overlap a source line 714a, a second portion 732 placed in such a position as not to overlap a source line 714a, and a third portion 733 connecting the first portion 731 to the second portion 732. The second portion 732 is placed at a kink portion 722a. In an in-plane switching liquid crystal display device, the kink portion 722a is a boundary region between different directions of electric fields that activate the liquid crystals in the liquid crystal layer 3 and a region that contributes less to a display. Placing the second portion 732 over the kink portion 722a makes it possible to avoid a decrease in luminance. Furthermore, the second portion 732 of one of the plurality of touch detection lines 730 and the second portion 732 of a touch detection line 730 that is adjacent to one of the plurality of touch detection lines 730 in the X1 direction are alternately arrayed side by side in the Y1 direction. The seventh embodiment makes it possible to increase the number of touch detection lines 730 while avoiding unevenness in display also in the active matrix substrate 701, which is driven by a triple gate driving method. Other components and effects of the seventh embodiment are similar to the components and effects of the first embodiment.

### Eighth Embodiment

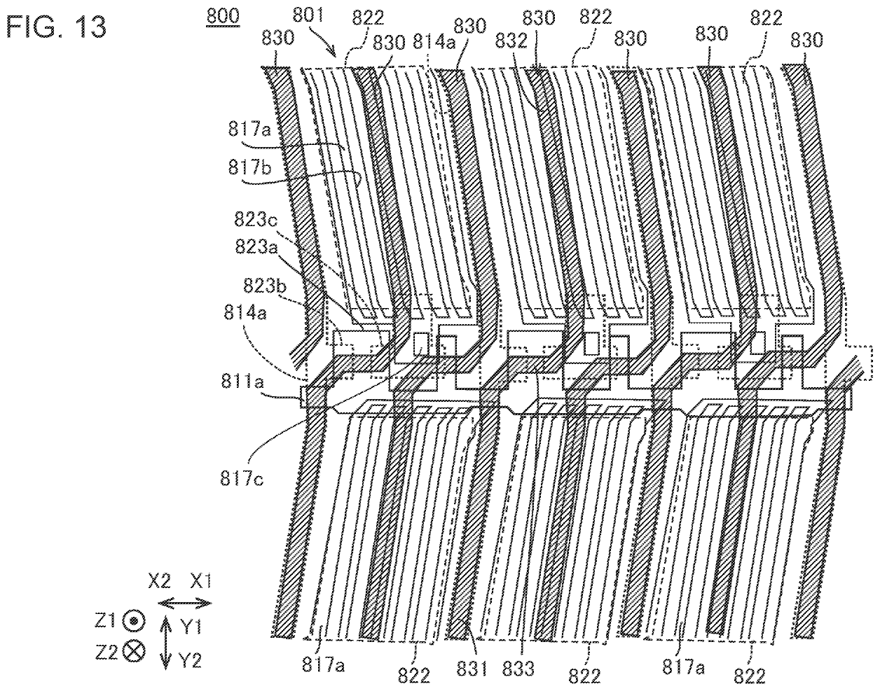

Next, a configuration of an in-cell touch panel 800 according to an eighth embodiment is described with reference to FIG. 13. In the eighth embodiment, an active matrix substrate 801 is configured to be driven by a single gate driving method. Components that are similar to those of the first embodiment are given the same reference signs as those of the first embodiment, and a description of such components is omitted.

FIG. 13 is a diagram showing the configuration of the in-cell touch panel 800 according to the eighth embodiment. The in-cell touch panel 800 includes an active matrix substrate 801. The active matrix substrate 801 includes pixel regions 822 (pixel electrodes), source lines 814a extending in the Y1 direction, gate lines 811a extending in the X1 direction, and touch detection lines 830. While the first embodiment is directed to a method by which a row of pixel regions 22 is driven by two gate lines, the eighth embodiment is directed to a method by which a row of pixel regions 822 is driven by one gate line 811a. Further, while the source lines 14a is provided one by one for two columns of pixel regions in the first embodiment, the source lines 814a are provided one by one for one column of pixel regions in the eighth embodiment. That is, the active matrix substrate 801 is configured to be driven by a single gate driving method.

Further, as shown in FIG. 13, a gate electrode 823a, a source electrode 823b, and a drain electrode 823c are placed in positions that are further forward in the Y2 direction than each of the pixel regions 822. A pixel electrode 817a is connected to the drain electrode 823c via a pixel contact hole 817c. The pixel electrode 817a is provided with a plurality of slits 817b.

Each of the touch detection lines 830 includes a first portion 831 placed in such a position as to overlap a source line 814a, a second portion 832 placed in such a position as not to overlap a source line 814a, and a third portion 833 connecting the first portion 831 to the second portion 832. In each of the pixel regions 822, a pixel electrode 817a is placed. The second portion 832 is placed in a position that is at substantially equal distances from two adjacent source lines 814a and in such a position as to overlap the pixel electrode 817a. Furthermore, the second portion 832 of one of the plurality of touch detection lines 830 and the second portion 832 of a touch detection line 830 that is adjacent to one of the plurality of touch detection lines 830 in the X1 direction are alternately arrayed side by side in the Y1 direction. The eighth embodiment makes it possible to increase the number of touch detection lines 830 while avoiding unevenness in display also in the active matrix substrate 801, which is driven by a single gate driving method. Other components and effects of the eighth embodiment are similar to the components and effects of the first embodiment.

While the foregoing has described embodiments, the aforementioned embodiments are merely examples in which the present disclosure is carried out. Therefore, the present disclosure is not limited to the aforementioned embodiments and can be carried out with appropriate modifications to the aforementioned embodiments without departing from the scope of the present disclosure.

(1) While the first to eighth embodiments have illustrated an example in which all of the touch detection lines provided in the active matrix substrate are provided with first to third portions, the present disclosure is not limited to this. That is, at least two of the touch detection lines provided in the active matrix substrate need only be provided with first to third portions.

(2) While the first to eighth embodiments have been directed to examples of liquid crystal display devices, the present disclosure is not limited to this. For example, the first to eighth embodiments may be directed to e-paper devices (microcapsule electrophoretic display panels), or the first to fifth embodiments may be directed to organic EL display devices.

(3) While the first to eighth embodiments have illustrated an example in which a touch detection line is provided with a fourth portion and a fifth portion, the present disclosure is not limited to this. That is, a touch detection line may be composed only of first to third portions.

(4) While the first to eighth embodiments have illustrated examples of materials of the layers, the present disclosure is not limited to this. For example, the touch detection line layer may be composed of ITO.

(5) While the first to eighth embodiments have illustrated an example in which the third portion is placed in such a position as to overlap the black matrix, the present disclosure is not limited to this. For example, the third portion may be placed in such a position as to overlap a color filter or may be placed in such a position as not to overlap the color filter or the black matrix.

(6) While the first to eighth embodiments have illustrated an example in which the touch detection line layer 15, the second insulating layer 12c, the common electrode layer 16, the third insulating layer 12d, and the pixel electrode layer 17 are stacked in this order from the substrate 10, the present disclosure is not limited to this. For example, the common electrode layer 16, the second insulating layer 12c, the touch detection line layer 15, the third insulating layer 12d, and the pixel electrode layer 17 may be stacked in this order from the substrate 10, or the pixel electrode layer 17, the second insulating layer 12c, the touch detection line layer 15, the third insulating layer 12d, and the common electrode layer 16 may be stacked in this order from the substrate 10. In a case where the common electrode layer 16 is closer to the liquid crystal layer 3 than is the pixel electrode layer 17, the plurality of slits 17b formed in each of the pixel electrodes 17a in the first to eighth embodiments are formed in each of the touch detection electrodes 16a. Further, a configuration without the planarizing layer 12e may be set up.

The aforementioned configurations can also be described in the following manner.

According to a first configuration, there is provided an active matrix substrate having a plurality of pixel regions arranged in a matrix in a first direction and a second direction intersecting the first direction. The active matrix substrate includes a plurality of gate lines, a plurality of source lines, and a plurality of touch detection lines. The plurality of gate lines extend in the first direction. The plurality of gate lines are arrayed in the second direction. The plurality of gate lines are formed in a gate line layer. The plurality of source lines extend in the second direction. The plurality of source lines are arrayed in the first direction. The plurality of source lines are formed in a source line layer. The plurality of touch detection lines are connected separately to each of a plurality of touch detection electrodes, arrayed in the first direction, and at least partly formed in a touch detection line layer. Each of the plurality of touch detection lines includes a first portion, a second portion, and a third portion. The first portion extends in the second direction in such a position as to overlap any one of the plurality of source lines. The first portion is formed in the touch detection line layer. The second portion extends in the second direction in such a position as not to overlap the plurality of source lines. The third portion connects the first portion to the second portion. The second portion of one of the plurality of touch detection lines and the second portion of a touch detection line that is adjacent to one of the plurality of touch detection lines in the first direction are alternately arrayed side by side in the second direction (first configuration).

Note here that increasing the number of touch detection electrodes for finer-resolution touch detection causes an increase in the number of touch detection lines. In a case where the number of touch detection lines is equal to the number of source lines, the source lines and the touch detection lines can be alternately arranged side by side; however, in a case where the number of touch detection lines is larger than the number of source lines, some of the touch detection lines are placed in such positions as to overlap some of the source lines. This causes a difference between the capacitance of a touch detection line placed over a source line and the capacitance of a touch detection line placed in such a position as not to overlap a source line. Due to this difference in capacitance, there are variations in the potential of a plurality of touch detection electrodes (i.e. the potential of a plurality of common electrodes). The variations in the potential of the plurality of touch detection electrodes undesirably lead to unevenness in display. On the other hand, according to the first configuration, each of the plurality of touch detection lines includes a first portion that is a portion overlapping a source line and that is formed in the touch detection line layer and a second portion that is a portion not overlapping a source line. This causes any of the plurality of touch detection lines to include a portion overlapping a source line and a portion not overlapping a source line. This makes it possible to better reduce variations in the capacitance of the plurality of touch detection lines than in a case where the plurality of touch detection lines include a touch detection line wholly overlapping a source line and a touch detection line not overlapping a source line at all. As a result of this, even in a case where the number of touch detection lines is increased, variations in the potential of the plurality of touch detection electrodes can be reduced, so that unevenness in display on the in-cell touch panel can be avoided.

In the first configuration, each of the plurality of touch detection lines may further include a fourth portion formed as an extension in the second direction of the first portion and a fifth portion connecting the fourth portion to the second portion (second configuration).

According to the second configuration, the fifth portion makes it possible to connect the second portion to the fourth portion formed as an extension in the second direction of the first portion.

In the first or second configuration, the third portion may be placed between ones of the plurality of pixel regions that are adjacent to each other in the second direction (third configuration).

According to the third configuration, the third portion of each of the touch detection lines does not overlap the pixel regions, so that blocking by the third portion of light passing through the pixel regions can be avoided.

In any one of the first to third configurations, the plurality of gate lines may be placed two by two between ones of the plurality of pixel regions that are adjacent to each other in the second direction. The second portion may be placed between ones of the plurality of pixel regions that are adjacent to each other in the first direction (fourth configuration).

According to the fourth configuration, the active matrix substrate can be driven by a dual gate driving method. This causes there to be a position where no source line is placed between a plurality of pixel regions that are adjacent to each other in the first direction, thus making it possible to place the second portion in that position. As a result of this, the second portion of each of the touch detection lines does not overlap the pixel regions, so that blocking by the second portion of light passing through the pixel regions can be avoided.

In the fourth configuration, the active matrix substrate may further include a conductor line that is different from the plurality of source lines and that is formed in the source line layer. The conductor line is placed in such a position as to overlap the second portion (fifth configuration).

According to the fifth configuration, the placement of the conductor line makes it possible to reduce a difference between the capacitance of the first portion of each of the touch detection lines and the capacitance of the second portion of the touch detection line.

In the fifth configuration, the conductor line may be connected to the second portion (sixth configuration).

According to the sixth configuration, the electric resistance of each of the touch detection lines can be reduced. Further, since the conductor line can be utilized as a redundant line of the touch detection line, the redundancy of the active matrix substrate can be improved.

In any one of the first to sixth configurations, the third portion may be placed between ones of the plurality of touch detection electrodes that are adjacent to each other in the second direction (seventh configuration).

The seventh configuration makes it possible to substantially equalize the capacitance of a plurality of touch detection electrodes placed across a plurality of touch detection electrodes that are adjacent to each other in the second direction.

In any one of the first to sixth configurations, the third portion may be placed in such a position as to overlap a central portion in the second direction of one of the plurality of touch detection electrodes (eighth configuration).

The eighth configuration makes it possible to substantially equalize the capacitance of the plurality of touch detection lines in regions overlapping the touch detection electrodes.

In any one of the first to sixth configurations, the plurality of touch detection lines may include a first touch detection line and a second touch detection line placed at a distance in the first direction from the first touch detection line. The third portion of the first touch detection line may be placed in a position that is different in the second direction from a position of the third portion of the second touch detection line (ninth configuration).

According to the ninth configuration, the position of the third portion of the first touch detection line and the position of the third portion of the second touch detection line are dispersedly placed the second direction. This makes it possible to avoid a situation where a difference in capacitance between gate lines attributed to the third portions affects a display.

In any one of the first to ninth configurations, the active matrix substrate may further include a pixel electrode provided in each of the plurality of pixel regions, the pixel electrode having a bent portion bent in the first direction. The second portion of one of the plurality of touch detection lines may be placed in such a position as to overlap the bent portion (tenth configuration).

According to the tenth configuration, a third portion connected to the second portion does not need to pass through such a position as to overlap the bent portion. This makes it possible to avoid the third portion becoming complex in shape.

In any one of the first to tenth configurations, the active matrix substrate may further include a pixel electrode provided in each of the plurality of pixel regions. The second portion of one of the plurality of touch detection lines may be placed in such a position as to overlap the pixel electrode (eleventh configuration).

The eleventh configuration makes it possible to increase the number of touch detection lines while avoiding unevenness in display even in a case where the active matrix substrate is driven by a single gate driving method.

According to a twelfth configuration, there is provided an in-cell touch panel including the active matrix substrate according to any one of the first to eleventh configurations and a plurality of touch detection electrodes placed in the active matrix substrate (twelfth configuration).

The twelfth configuration makes it possible to provide an in-cell touch panel that makes it possible to increase the number of touch detection lines while avoiding unevenness in display.

According to a thirteenth configuration, there is provided a display device including the active matrix substrate according to any one of the first to eleventh configurations and a counter substrate placed opposite the active matrix substrate (thirteenth configuration).

The thirteenth configuration makes it possible to provide a display device that makes it possible to increase the number of touch detection lines while avoiding unevenness in display.

In the thirteenth configuration, the third portion may be placed in such a position as to overlap a light-blocking member (fourteenth configuration).

According to the fourteenth configuration, the third portion is placed in a position where the light-blocking member, which is not used for a display, is placed. This makes it possible to avoid the third portion affecting a display.

The present disclosure contains subject matter related to that disclosed in Japanese Priority Patent Application JP 2023-209709 filed in the Japan Patent Office on Dec. 12, 2023, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. An active matrix substrate having a plurality of pixel regions arranged in a matrix in a first direction and a second direction intersecting the first direction, the active matrix substrate comprising:
a plurality of gate lines extending in the first direction, the plurality of gate lines being arrayed in the second direction, the plurality of gate lines being formed in a gate line layer;
a plurality of source lines extending in the second direction, the plurality of source lines being arrayed in the first direction, the plurality of source lines being formed in a source line layer; and
a plurality of touch detection lines connected separately to each of a plurality of touch detection electrodes, arrayed in the first direction, and at least partly formed in a touch detection line layer,
wherein
each of the plurality of touch detection lines includes
a first portion extending in the second direction in such a position as to overlap any one of the plurality of source lines, the first portion being formed in the touch detection line layer,
a second portion extending in the second direction in such a position as not to overlap the plurality of source lines, and
a third portion connecting the first portion to the second portion, and
the second portion of one of the plurality of touch detection lines and the second portion of a touch detection line that is adjacent to one of the plurality of touch detection lines in the first direction are alternately arrayed side by side in the second direction.

2. The active matrix substrate according to claim 1, wherein each of the plurality of touch detection lines further includes a fourth portion formed as an extension in the second direction of the first portion and a fifth portion connecting the fourth portion to the second portion.

3. The active matrix substrate according to claim 1, wherein the third portion is placed between ones of the plurality of pixel regions that are adjacent to each other in the second direction.

4. The active matrix substrate according to claim 1, wherein
the plurality of gate lines are placed two by two between ones of the plurality of pixel regions that are adjacent to each other in the second direction, and
the second portion is placed between ones of the plurality of pixel regions that are adjacent to each other in the first direction.

5. The active matrix substrate according to claim 4, further comprising a conductor line that is different from the plurality of source lines and that is formed in the source line layer,
wherein the conductor line is placed in such a position as to overlap the second portion.

6. The active matrix substrate according to claim 5, wherein the conductor line is connected to the second portion.

7. The active matrix substrate according to claim 1, wherein the third portion is placed between ones of the plurality of touch detection electrodes that are adjacent to each other in the second direction.

8. The active matrix substrate according to claim 1, wherein the third portion is placed in such a position as to overlap a central portion in the second direction of one of the plurality of touch detection electrodes.

9. The active matrix substrate according to claim 1, wherein
the plurality of touch detection lines includes a first touch detection line and a second touch detection line placed at a distance in the first direction from the first touch detection line, and
the third portion of the first touch detection line is placed in a position that is different in the second direction from a position of the third portion of the second touch detection line.

10. The active matrix substrate according to claim 1, further comprising a pixel electrode provided in each of the plurality of pixel regions, the pixel electrode having a bent portion bent in the second direction,
wherein the second portion of one of the plurality of touch detection lines is placed in such a position as to overlap the bent portion.

11. The active matrix substrate according to claim 1, further comprising a pixel electrode provided in each of the plurality of pixel regions,
wherein the second portion of one of the plurality of touch detection lines is placed in such a position as to overlap the pixel electrode.

12. An in-cell touch panel comprising:
the active matrix substrate according to claim 1; and
a plurality of touch detection electrodes placed in the active matrix substrate.

13. A display device comprising:
the active matrix substrate according to claim 1; and
a counter substrate placed opposite the active matrix substrate.

14. The display device according to claim 13, wherein
the counter substrate includes a light-blocking member, and
the third portion is placed in such a position as to overlap the light-blocking member.
